(19) United States
(12) Patent Application Publication
(10) Pub. No.: US 2007/0061687 A1
(43) Pub. Date: Mar. 15, 2007

(54) Soft decoding method and apparatus, error correction method and apparatus, and soft output method and apparatus

(75) Inventor: Sung-hee Hwang, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/512,365

(22) Filed: Aug. 30, 2006

(30) Foreign Application Priority Data
Aug. 31, 2005 (KR) 2005-80964

(51) Int. Cl. H03M 13/00

(52) U.S. Cl. 714/780

(57) ABSTRACT

Provided are a decoding method and apparatus, an error correction method and apparatus, and a soft output method and apparatus to improve the performance of soft error correction. A method of decoding a codeword encoded into a code that can be soft iterative decoded includes: receiving a soft value of each bit of the codeword; generating a defect signal for the received codeword; and changing a soft value of all bits corresponding to the generated defect signal or some of the bits corresponding to the generated defect signal into a predetermined value to perform error correction.

### CROSS-REFERENCE TO RELATED APPLICATION

This application claims the benefit of Korean Patent Application No. 2005-80964, filed on Aug. 31, 2005, in the Korean Intellectual Property Office, the disclosure of which is incorporated herein in its entirety by reference.

### BACKGROUND OF THE INVENTION

1. Field of the Invention

Aspects of the present invention relate to a decoding method and apparatus, an error correction method and apparatus, and a soft output method and apparatus to improve the performance of soft error correction.

2. Description of the Related Art

As the density of data storage media and the speed of data transmission have increased, the amount of data reproduced or transmitted per unit time on a communication channel for data transmission including cable/wireless communication and optical communication has also increased. As a result, channel conditions can worsen and more errors can occur. For example, an optical information storage medium stores a large amount of data per physical unit length due to its high density, and thus can have more errors, such as due to dust, scratches, or fingerprints. In cable/wireless communication, since the amount of data transmitted per unit time increases due to the high display quality of data, the amount of errors of received data caused by a communication failure can also increase. Consequently, cable/wireless communication should typically use an error correction method or an error correction code having high error correction performance in a communication channel.

An error correction method or error correction code used is soft iterative decoding performs error correction through iterative correction with reference to a soft value of an input bit (e.g., 0.2 or 0.9), such as turbo code decoding and low density parity check code (LDPC) decoding, instead of performing error correction with reference to the hard value (0 or 1) of an input bit, such as conventional Reed-Solomon coding. The soft value of an input bit can be generally indicated by the probability of an input hard value being “0” or “1”.

FIG. 1 is a block diagram of a known soft encoding/decoding apparatus. Referring to FIG. 1, a soft encoding/decoding apparatus 100 includes a turbo/LDPC encoding unit 110, a modulating unit 120, a recording/reading unit 130, a soft demodulating unit 150, and a turbo/LDPC decoding unit 160. The turbo/LDPC encoding unit 110 performs encoding using a predetermined encoding method for error correction of input data (e.g., soft encoding, such as LDPC encoding or turbo encoding). The modulating unit 120 modulates data output from the turbo/LDPC encoding unit 110 using a predetermined method (e.g., using a run length limited (RLL) code).

The recording/reading unit 130 records the modulated data on a recording medium 140 and reads data recorded on the recording medium 140. The soft demodulating unit 150 receives data indicating the probability value of codeword from the recording/reading unit 130 and outputs a log likelihood ratio (LLR) indicating the probability value of each bit of a data word. The turbo/LDPC decoding unit 160 receives soft values output from the soft demodulating unit 150, performs soft decoding corresponding to the predetermined encoding method used in the turbo/LDPC encoding unit 110, and outputs decoded data.

In a soft decoding method, since error correction is performed using a soft value, the performance of error correction is typically dependent on the reliability of the soft value of an input bit. As a result, there is a need to improve the performance of error correction using the reliability of a soft value.

### SUMMARY OF THE INVENTION

Several example embodiments and aspects of the present invention provide a decoding method and apparatus, an error correction method and apparatus, and a soft output method and apparatus to improve the performance of soft error correction.

According to an example embodiment and aspects of the present invention, there is provided a method of decoding a codeword encoded into a code that can be soft iterative decoded. The method includes: receiving soft values, each soft value corresponding to a bit of the codeword; generating a defect signal corresponding to the received codeword; and changing soft values of one or more bits, such as, for example all or some bits, corresponding to the generated defect signal into a predetermined value to perform error correction.

According to aspects of the invention, the predetermined value can indicate that the probability value that a corresponding bit is “0” and the probability value that the corresponding bit is “1” are the same. Also, the predetermined value can be determined by an error correction characteristic of a low density parity check. Further, the receiving of the soft value can include receiving the soft values from a communication channel. Also, according to aspects of the invention, the receiving of the soft values can include receiving the soft values from an information storage medium.

The generation of the defect signal, according to aspects of the invention, can include detecting at least one or more sections, including a section where data is not synchronous in data reception, a section where a phase-locked loop (PLL) error occurs, a section where a synchronization error is generated during soft demodulation, or a section including a pattern that does not exist among modulated patterns, and generating a defect signal corresponding to the entire detected section or a part of the entire detected section.

Further, according to aspects of the invention, the generating of the defect signal can include detecting at least one or more sections, including a section where a servo error occurs, a section where the reliability of data is determined to be low corresponding to an amount of reflection from a pickup being relatively large or small, a section where a PLL or a synchronization error is detected, or a section including a pattern that does not exist among modulated patterns, and generating a defect signal corresponding to the entire detected section or a part of the entire detected section.

According to another example embodiment and aspects of the present invention, there is provided a method of performing error correction on a codeword encoded into a code that can be soft iterative decoded. The method includes: changing soft values of one or more bits, such as, for example, all or some bits, corresponding to a defect signal of the encoded codeword into a predetermined value; and performing iterative correction based on each changed soft value.

According to still another example embodiment and aspects of the present invention, there is provided an apparatus to decode a codeword encoded into a code that can be soft iterative decoded. The apparatus includes: a receiving unit to receive soft values, each soft value corresponding to a bit of the codeword; a defect signal generating unit to generate a defect signal corresponding to the received codeword; and a soft decoder to change soft values of one or more bits, such as, for example, all or some bits, corresponding to the generated defect signal into a predetermined value to perform error correction.

According to yet another example embodiment and aspects of the present invention, there is provided an apparatus to perform error correction on a codeword encoded into a code that can be soft iterative decoded. The apparatus includes: a soft decoder to change soft values of one or more bits, such as, for example, all or some bits, corresponding to a defect signal of the encoded codeword into a predetermined value; and performing iterative correction based on each changed soft value.

According to a further example embodiment and aspects of the present invention, there is provided a method of outputting a soft value from a codeword encoded into a code that can be soft iterative decoded. The method includes: receiving soft values, each soft value corresponding to a bit of the codeword; generating a defect signal corresponding to the received codeword; and changing soft values of one or more bits, such as, for example, all or some bits, corresponding to the generated defect signal into a predetermined value and outputting each changed soft value.

According to yet another example embodiment and aspects of the present invention, there is provided an apparatus to output a soft value from a codeword encoded into a code that can be soft iterative decoded. The apparatus includes: a receiving unit to receive soft values, each soft value corresponding to a bit of the codeword; a defect signal generating unit to generate a defect signal corresponding to the received codeword; and a soft-in soft-out (SISO) processing unit to change soft values of one or more bits, such as for example, all or some bits, corresponding to the generated defect signal into a predetermined value and to output each changed soft value.

Additional aspects and/or advantages of the invention are set forth in the description which follows or are evident from the description, or can be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a known soft encoding/decoding apparatus;

FIG. 2 is a block diagram of a soft output apparatus that outputs the soft value of data received from a communication channel according to an embodiment of the present invention;

FIG. 3 is a block diagram of a soft decoding apparatus that performs soft decoding on data received from a communication channel according to an embodiment of the present invention;

FIG. 4 is a block diagram of a soft decoding apparatus that performs soft decoding on data received from a communication channel according to another embodiment of the present invention;

FIG. 5 is a schematic block diagram of a recording device that performs soft encoding on data and records the soft-encoded data on an optical disk;

FIG. 6 is a block diagram of a soft output apparatus that outputs the soft value of data read from a data storage medium according to an embodiment of the present invention;

FIG. 7 is a block diagram of a soft decoding apparatus that performs soft decoding on data read from a data storage medium and reproduces the soft-decoded data according to an embodiment of the present invention;

FIG. 8 is a block diagram of a soft decoding apparatus that performs soft decoding on data read from a data storage medium and reproduces the soft-decoded data according to another embodiment of the present invention;

FIGS. 9A through 9C illustrate examples of error correction without changing a defective section corresponding to a defect signal;

FIG. 10 illustrates error correction in which a defective section corresponding to a defect signal is changed into a predetermined value “0” according to an embodiment and aspects of the present invention;

FIG. 11 illustrates error correction in which a defective section corresponding to a defect signal is changed into a predetermined value “1” according to an embodiment and aspects of the present invention;

FIG. 12 illustrates error correction in which a defective section corresponding to a defect signal is changed into a predetermined value “−1” according to an embodiment and aspects of the present invention;

FIG. 13 is a flowchart illustrating a soft output method according to an embodiment of the present invention;

FIG. 14 is a flowchart illustrating a soft decoding method according to an embodiment of the present invention;

FIG. 15 is a flowchart illustrating a soft decoding method according to another embodiment of the present invention; and

FIG. 16 is a graph for comparing the performance of LDPC error correction according to known art and the performance of LDPC erasure correction according to aspects of the present invention.

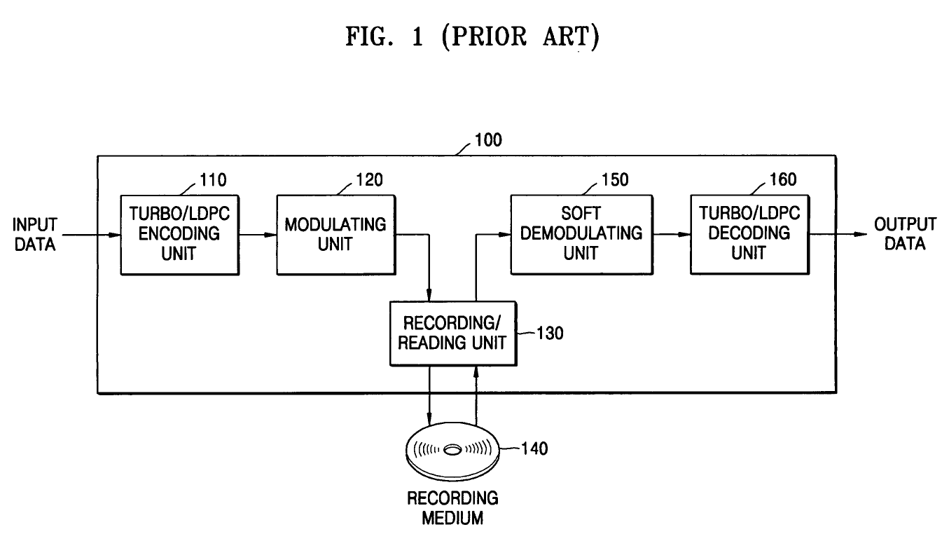

### DETAILED DESCRIPTION OF THE EMBODIMENTS

Reference will now be made in detail to embodiments of the invention, examples of which are illustrated in the accompanying drawings, wherein like reference numerals refer to the like elements throughout. The embodiments are described below in order to explain aspects of the invention by referring to the figures, with well-known functions or constructions not necessarily being described in detail.

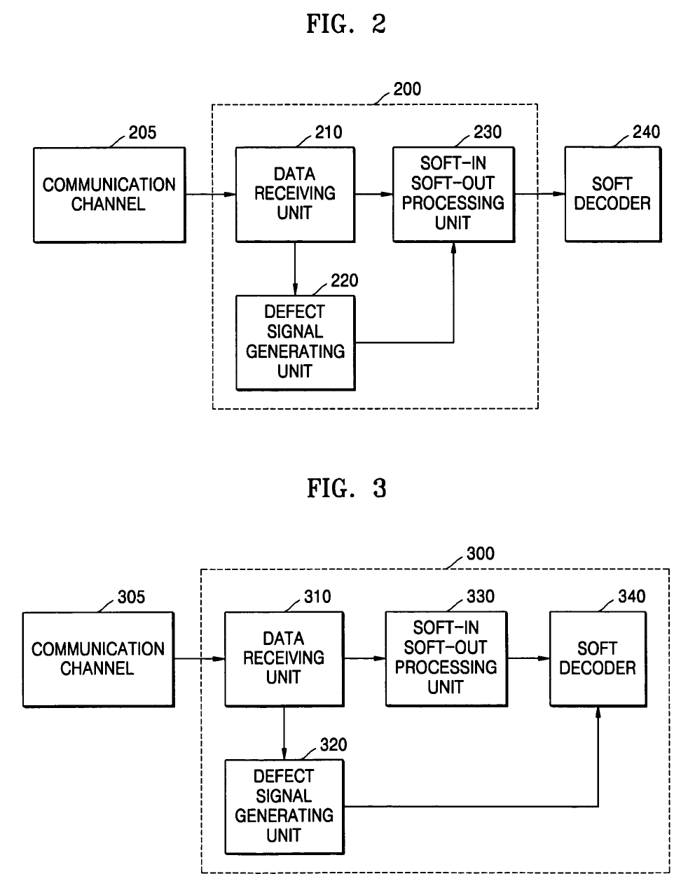

FIG. 2 is a block diagram of a soft output apparatus 200 that outputs the soft value of data received from a communication channel according to an embodiment of the present invention. The soft output apparatus 200 illustrated in FIG. 2 changes a soft value with reference to a defect signal for soft decoding and outputs the changed soft value to a soft decoder 240.

Referring to FIG. 2, the soft output apparatus 200 according to an embodiment of the present invention includes a data receiving unit 210, a defect signal generating unit 220, and a soft-in soft-out (SISO) processing unit 230. The data receiving unit 210 receives analog signals from a communication channel 205 for cable/wireless communication or optical communication, converts received analog signals into digital signals (soft values) having a signal level, and outputs the converted soft values to the SISO processing unit 230 through a phase locked loop (PLL) that generates a clock.

The defect signal generating unit 220 detects a defective section having a high possibility of a defect occurring (i.e., a defective section determined as having a low data reliability) from received data, and generates a defect signal for the detected defective section. In this regard and by way of example, the defect signal generating unit 220 receives information to determine whether a signal has a defect from the data receiving unit 210. The defect signal generating unit 220 determines that the signal has a defect if the received information does not reach or exceed a predetermined criterion, indicating detection of a defective section having a high possibility of a defect occurring. In response to detecting a defective section, the defect signal generating unit 220 generates a defect signal for the detected defective section, and transmits the generated defect signal to the SISO processing unit 230.

The information to determine whether a signal has a defect includes information about whether data is not synchronous in data reception or whether a PLL error occurs. Since the reliability of data in a section where data is not synchronous or a synchronous section including a section having a PLL error is low, a defect signal can be generated for the entire section or a part of the section where data is not synchronous or the synchronous section including a section having a PLL error.

The SISO processing unit 230 outputs a soft signal regarded as being most similar to a signal received from the data receiving unit 210 through maximum likelihood detection using a soft output viterbi algorithm (SOVA) or outputs a soft value by performing soft demodulation on a signal modulated in data transmission, for example. In this regard and by way of example, the SISO processing unit 230 according to an embodiment and aspects of the present invention receives the defect signal from the defect signal generating unit 220, changes the soft values of all or some bits corresponding to a defective section for which the defect signal is generated into a predetermined value, and outputs the changed soft values to a soft decoder 240.

The predetermined value can vary, and the probability of a bit being “0” and the probability of the bit being “1” can be the same. In this regard and by way of example, a predetermined value between “0” and “1” can be set to a mean value between “0” and “1” (i.e., “0.5” or a value that swings around “0.5”). Also, the performance of error correction can be improved through erasure correction of a decoder by setting the predetermined value to “0.5” because the reliability of a signal corresponding to a defective section is typically low. If values “−1” and “1” for hard bits are input to the soft decoder 240, a predetermined value for a bit corresponding to the defective section can be set to “0” or a value that swings around “0”, for example. As to be described further, other predetermined values can be set according to aspects of the present invention. The soft decoder 240 performs error correction through soft iterative correction, such as LDPC encoding or turbo encoding, using a soft value input from the SISO processing unit 230. As shown in FIG. 2, the soft decoder 240 can be external to the soft output apparatus 200.

FIG. 3 is a block diagram of a soft decoding apparatus 300 that performs soft decoding on data received from a communication channel according to an embodiment and aspects of the present invention. Referring to FIG. 3, the soft decoding apparatus 300 includes a data receiving unit 310, a defect signal generating unit 320, a SISO processing unit 330, and a soft decoder 340. The data receiving unit 310 receives analog signals from a communication channel 305 for cable/wireless communication or optical communication, converts received analog signals into digital signals (soft values) having a signal level, and outputs the soft values to the SISO processing unit 330 through a phase locked loop (PLL) that generates a clock. As shown in FIG. 3, the soft decoder 340 can be included in the soft decoding apparatus 300 to perform error correction.

The defect signal generating unit 320 detects a defective section having a high possibility of a defect occurring (i.e., a defective section determined as having low data reliability) from received data and generates a defect signal for the detected defective section. In this regard and by way of example, the defect signal generating unit 320 receives information to determine whether a signal has a defect from the data receiving unit 310 and determines that the signal has a defect if the received information does not reach or exceed a predetermined criterion, indicating detection of a defective section having a high possibility of a defect occurring. In response to detection of a defective section, the data receiving unit 310 generates a defect signal for the determined defective section, and transmits the generated defect signal to the soft decoder 340.

Typically, the information for determining whether a signal has a defect includes information about whether data is not synchronous in data reception or a PLL error occurs. Since the reliability of data in a section where data is not synchronous or a synchronous section including a section having a PLL error is low, a defect signal can be generated for the entire or a part of the section where data is not synchronous or the synchronous section including a section having a PLL error, for example. The SISO processing unit 330 outputs soft signals that are similar to signals received from the data receiving unit 310 through a maximum likelihood detection using a soft output viterbi algorithm (SOVA), or outputs soft values by performing soft demodulation on a signal modulated in data transmission, for example.

The soft decoder 340 performs error correction using soft values input from the SISO processing unit 330. In this regard and by way of example, the soft decoder 340 uses the defect signal provided from the defect signal generating unit 320 for error correction. The soft decoder 340 changes the soft values of all or some bits corresponding to a defective section for which the defect signal is generated into a predetermined value for error correction. The predetermined value can vary, but the probability of a bit being “0” and the probability of the bit being “1” can be the same, for example. As to be described further, other predetermined values can be set according to aspects of the invention. In addition, an error correction method, according to aspects of the present invention, can be applied to soft error correction methods that perform iterative correction using a soft value, instead of a hard value, including LDPC coding and turbo coding, for example.

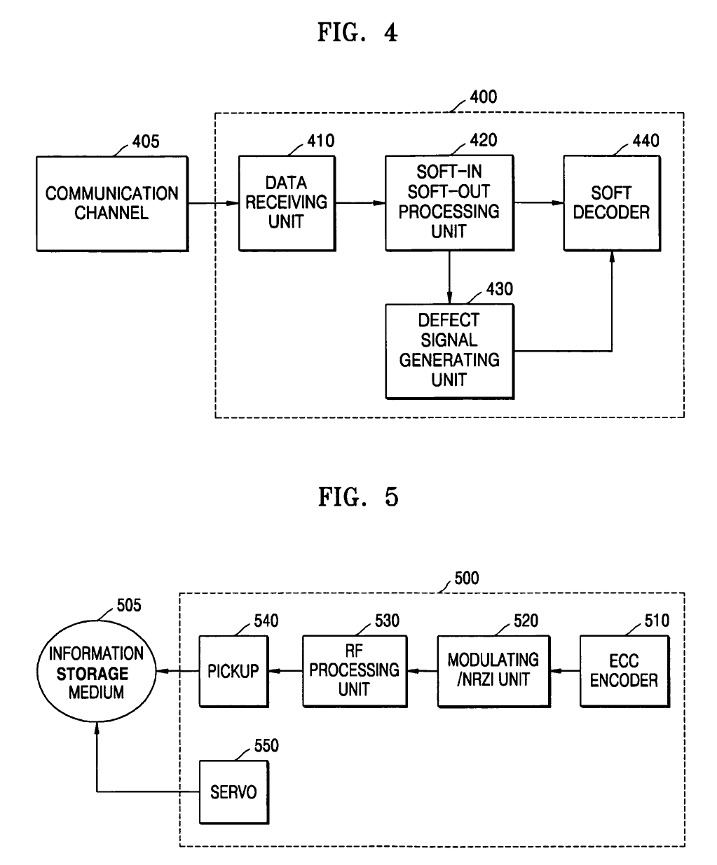

FIG. 4 is a block diagram of a soft decoding apparatus 400 that performs soft decoding on data received from a communication channel according to another embodiment and aspects of the present invention. Referring to FIG. 4, the soft decoding apparatus 400 includes a data receiving unit 410, a SISO processing unit 420, a defect signal generating unit 430, and a soft decoder 440. The operations of the data receiving unit 410, the SISO processing unit 420, and the soft decoder 440 are the same as, or similar to, those of the data receiving unit 310, the SISO processing unit 330, and the soft decoder 340 illustrated in FIG. 3, as described.

The configuration and/or operation of the soft decoding apparatus 400, as shown in FIG. 4, is different from that of the soft decoding apparatus 300, as shown in FIG. 3, in that the defect signal generating unit 430 generates a defect signal during SISO processing. In this regard and by way of example, the defect signal generating unit 430 receives information to determine whether a signal has a defect from the SISO processing unit 420 and generates a defect signal. The information to determine whether a signal has a defect includes information about a section having a synchronization error generated during soft demodulation or a section including a pattern that does not exist among modulated patterns. If it is determined that there is a high possibility of a section having a defect based on the received information, the defect signal generating unit 430 regards the determined section or a synchronization (sync) unit section including the determined section as a defective section, generates a defect signal for the defective section, and outputs the defect signal to the soft decoder 440. The soft decoder 440 receives the defect signal from the defect signal generating unit 430 and performs error correction with reference to the received defect signal.

An example where a soft decoding method according to an embodiment and aspects of the present invention is applied to reproduction of data from an information storage medium is described with reference to FIGS. 5 through 8. FIG. 5 is a schematic block diagram of a recording device 500 that performs soft encoding on data and records the soft-encoded data on an optical disk. Referring to FIG. 5, the recording device 500 includes an error correction code (ECC) encoder 510, a modulating/non return to zero inverted (NRZI) unit 520, a radio frequency (RF) processing unit 530, a pickup 540, and a servo 550.

To record data on an information storage medium 505, the ECC encoder 510 encodes user data into an ECC code that can be soft-decoded in data reproduction and outputs the ECC-encoded data to the modulating/NRZI unit 520. The modulating/NRZI unit 520 modulates the ECC-encoded data into an RLL code, constructs a plurality of recording frames that have predetermined units and are divided into sync blocks, converts the RLL code into a NRZI signal, and outputs the NRZI signal to the RF processing unit 530.

The RF processing unit 530 generates a recording waveform to record the received NRZI signal and outputs the recording waveform to the pickup 540. The pickup 540 radiates light onto the data storage medium 505 according to the generated recording waveform for data recording. The servo 550 performs servo control to drive the information storage medium 505.

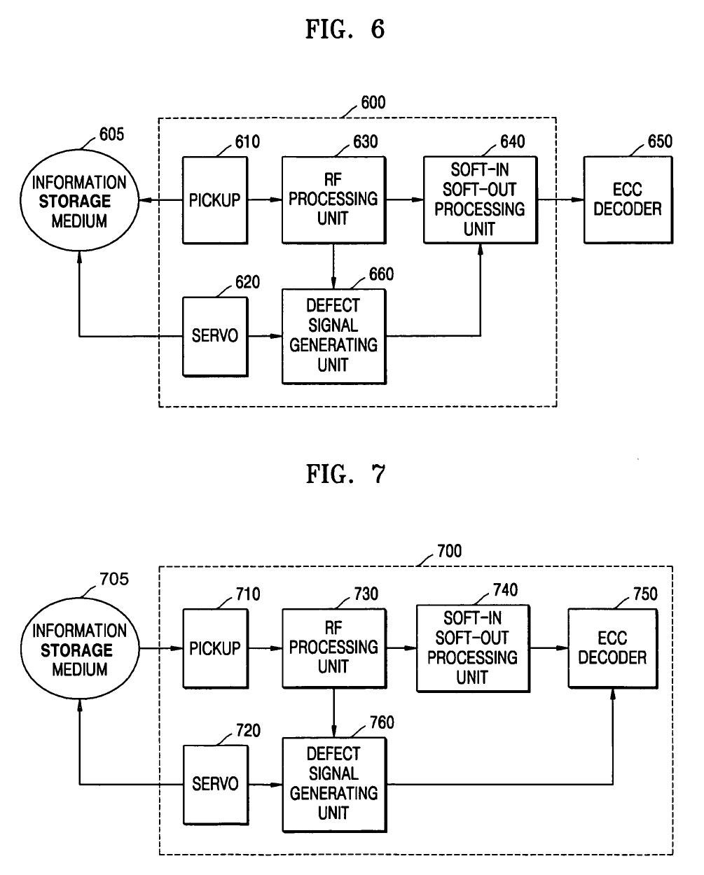

FIG. 6 is a block diagram of a soft output apparatus 600 that outputs the soft value of data read from an information storage medium according to an embodiment and aspects of the present invention. In FIG. 6, the soft output apparatus 600 outputs the soft values of signals received from an information storage medium 605, which is changed based on a defect signal, according to aspects of the present invention, to an ECC decoder 650.

Referring to FIG. 6, the soft output apparatus 600 includes a pickup 610, a servo 620, an RF processing unit 630, a defect signal generating unit 660, and a SISO processing unit 640. The servo 620 performs servo control on a position to be reproduced in the information storage medium 605 for reproduction of information recorded on the information storage medium 605. The pickup 610 reads electric signals from the position to be reproduced in the information storage medium 605 and outputs the electric signals to the RF processing unit 630. The RF processing unit 630 generates analog signals from the received electric signals. The generated analog signals are converted into digital signals using an analog-to-digital converter (ADC) (not shown) and a PLL (not shown), and a data clock is generated from the converted digital signals.

The SISO processing unit 640 decodes soft inputs using a soft output viterbi algorithm (SOVA) and soft demodulation and outputs soft outputs, for example. In this regard and by way of example, the SISO processing unit 640 outputs soft outputs corresponding to input signals based on digital signals and a clock generated from a PLL. The SISO processing unit 640 receives a defect signal from the defect signal generating unit 660, changes the soft values of all or some bits corresponding to a defective section for which the defect signal is generated into a predetermined value, and outputs the predetermined value to the ECC decoder 650. The predetermined value can vary, but the probability of a bit being “0” and the probability of the bit being “1” can be the same, for example.

The defect signal generating unit 660 receives information to determine whether a signal has a defect from the servo 620 or the RF processing unit 630, generates a defect signal according to a predetermined criterion, and outputs the generated defect signal to the SISO processing unit 640. The information to determine whether a signal has a defect, for example, includes information about whether the control of the servo 620 is unstable, such as a tracking error or a focusing error, or if the reliability of data is determined to be low because the amount of reflection from the pickup 610 is relatively large or small, and, thus, the level of the analog signal into which the electric signal is converted by the RF processing unit 630 is relatively low. The ECC decoder 650 performs error correction through soft iterative correction, such as LDPC decoding or turbo decoding, using soft value inputs from the SISO processing unit 640.

FIG. 7 is a block diagram of a soft decoding apparatus 700 that performs soft decoding on data read from an information storage medium 705 and reproduces the soft-decoded data according to an embodiment and aspects of the present invention. Referring to FIG. 7, the soft decoding apparatus 700 includes a pickup 710, a servo 720, an RF processing unit 730, a SISO processing unit 740, an ECC decoder 750, and a defect signal generating unit 760.

The servo 720 performs servo control on a position to be reproduced in the information storage medium 705 for reproduction of data recorded on the information storage medium 705. The pickup 710 reads electric signals from the position to be reproduced and outputs the read electric signals to the RF processing unit 730. The RF processing unit 730 generates analog signals from the received electric signals. The generated analog signals are converted into digital signals using an ADC (not shown) and a PLL (not shown), and a data clock is generated from the converted digital signals.

The SISO processing unit 740 decodes soft inputs using a SOVA and soft demodulation and outputs soft outputs. In this regard and by way of example, the SISO processing unit 740 outputs soft outputs corresponding to input signals based on digital signals and a clock generated from a PLL. The defect signal generating unit 760, according to an embodiment and aspects of the present invention, receives information to determine whether a signal has a defect from the servo 720 or the RF processing unit 730, generates a defect signal according to a predetermined criterion, and outputs the generated defect signal to the ECC decoder 750.

The information to determine whether a signal has a defect includes information about whether the control of the servo 720 is unstable, such as a tracking error or a focusing error, or if the reliability of data is determined to be low because the amount of reflection from the pickup 710 is relatively large or small, and, thus, the level of the analog signal into which the electric signal is converted by the RF processing unit 730 is relatively low.

The ECC decoder 750 performs error correction based on soft values input from the SISO processing unit 740. Also, the ECC decoder 750 refers to the defect signal received from the defect signal generating unit 760 for error correction. In this regard and by way of example, the ECC decoder 750 changes the soft values of all or some bits corresponding to a defective section for which the defect signal is generated into a predetermined value to perform error correction, for example.

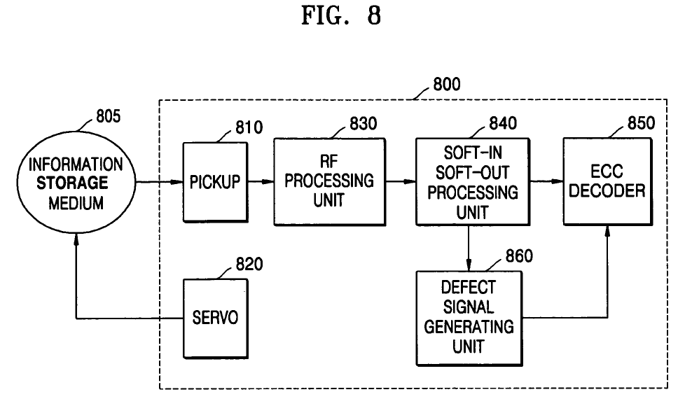

FIG. 8 is a block diagram of a soft decoding apparatus 800 that performs soft decoding on data read from a data storage medium 805 and reproduces the soft-decoded data according to another embodiment and aspects of the present invention. Referring to FIG. 8, the soft decoding apparatus 800 includes a pickup 810, a servo 820, an RF processing unit 830, a SISO processing unit 840, an ECC decoder 850, and a defect signal generating unit 860.

The operations of the pickup 810, the servo 820, the RF processing unit 830, the SISO processing unit 840, and the ECC decoder 850 are the same as, or similar to, those of the pickup 710, the servo 720, the RF processing unit 730, the SISO processing unit 740, and the ECC decoder 750, as described in connection with FIG. 7. However, the configuration and/or operation of the soft decoding apparatus 800, as shown in FIG. 8, is different from that of the soft decoding apparatus 700, as shown in FIG. 7, in that the defect signal generating unit 860 generates a defect signal during SISO processing.

In this regard and by way of example, the defect signal generating unit 860 receives information to determine whether a signal has a defect from the SISO processing unit 840 and generates a defect signal. The information to determine whether a signal has a defect includes a section having a synchronization error generated during soft demodulation of the SISO processing unit 840 or a section including a pattern that does not exist among modulated patterns, for example. If it is determined that there is a high possibility of a section having a defect based on the received information, the defect signal generating unit 860 regards the determined section or a sync unit section including the determined section as a defective section, generates a defect signal for the defective section, and outputs the defect signal to the ECC decoder 850. The ECC decoder 850 receives the defect signal from the defect signal generating unit 860 and performs error correction with reference to the received defect signal.

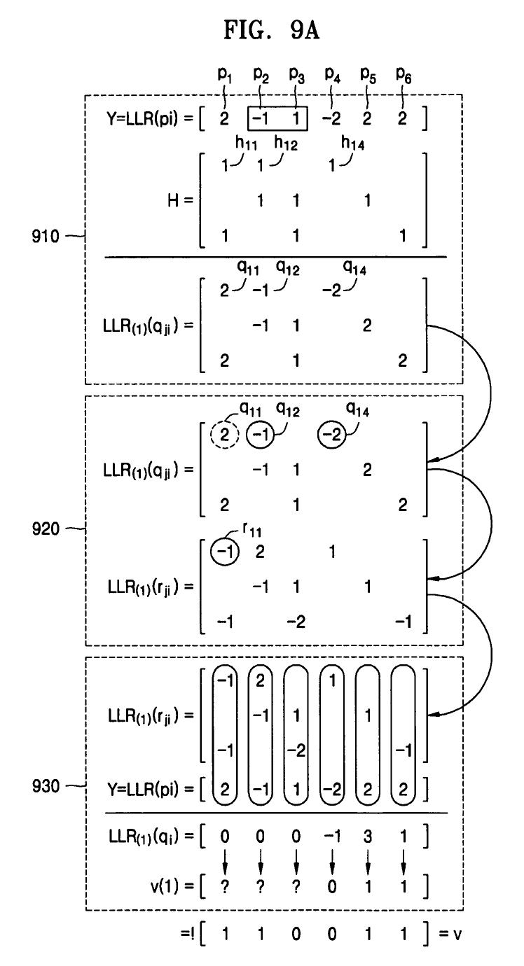

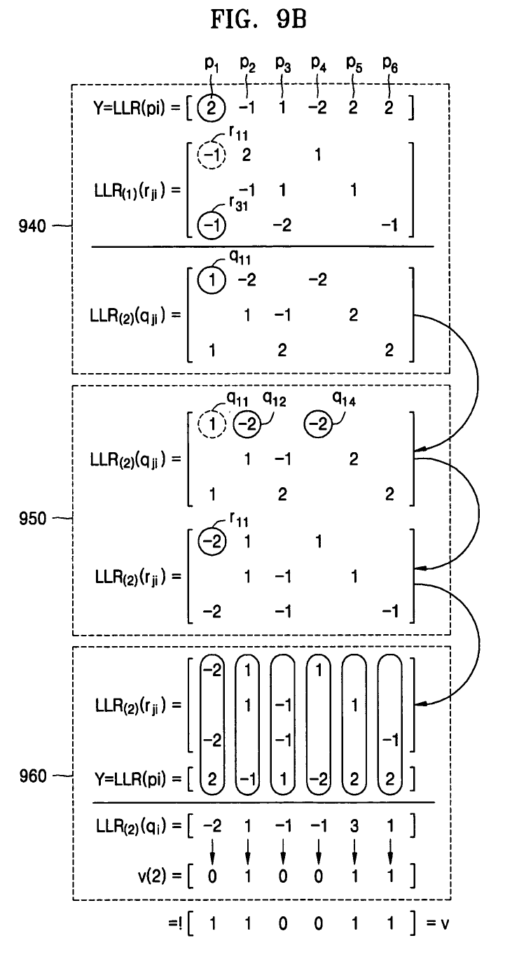

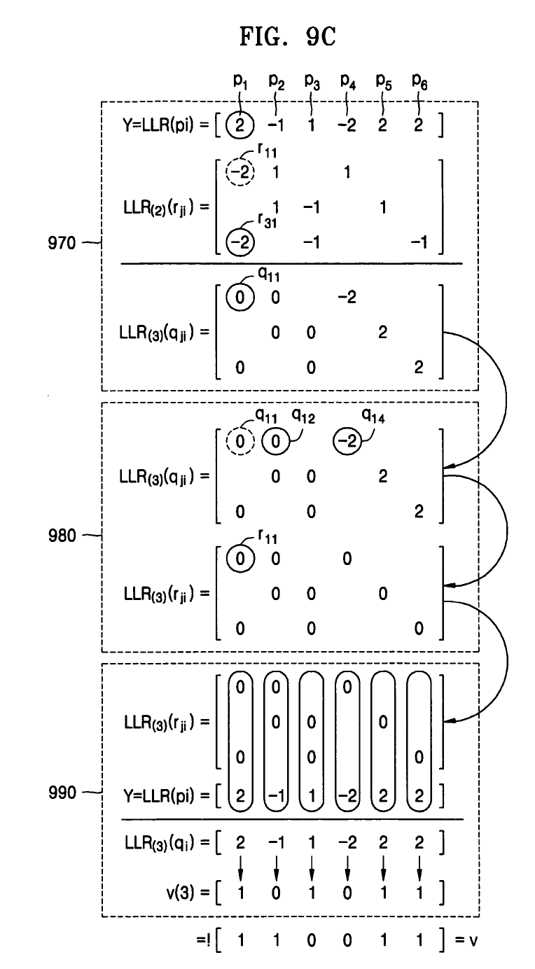

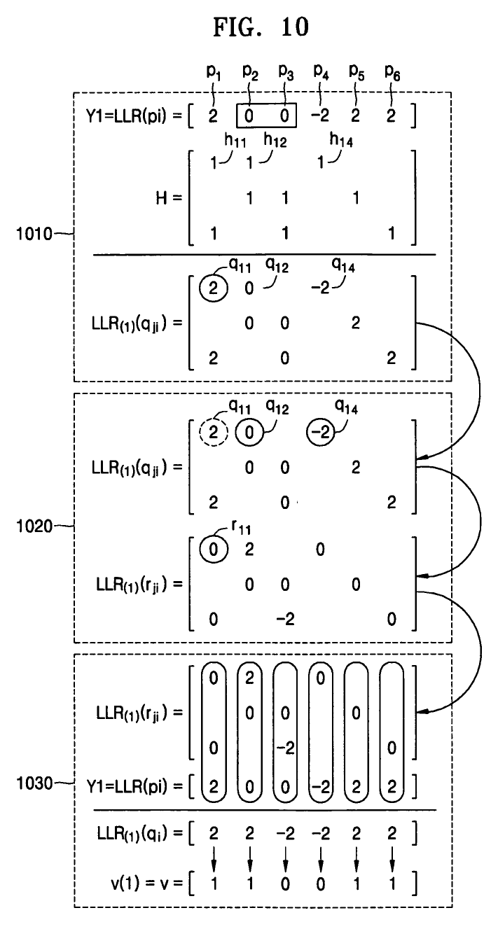

A soft decoding method that refers to a defect signal according to another embodiment and aspects of the present invention and a known soft decoding method that does not refer to a defect signal are described with reference to FIGS. 9A through 12. LDPC decoding used in these two soft decoding methods uses “MIN Approximation” of Section 4.5 Numerical Example in pp. 91-96 of “Constrained Coding and Soft Iterative Decoding” by John L. Fan and Kluwer Academic Publishers, the disclosure of which is incorporated herein by reference.

In the description of the soft decoding methods with reference to FIGS. 9A through 12, for example, a parity check matrix H is assumed to be as follows.

$$H = [ \begin{matrix}1 & 1 & 0 & 1 & 0 & 0 \\ 0 & 1 & 1 & 0 & 1 & 0 \\ 1 & 0 & 1 & 0 & 0 & 1\end{matrix} ]$$

Also, in the description of the soft decoding methods with reference to FIGS. 9A through 12, for example, a corresponding encoded codeword “v” is assumed to be as follows:

v=[1 1 0 0 1 1]

Further, in the description of the soft decoding methods with reference to FIGS. 9A through 12, for example, a soft output “y” that does not refer to a defect signal output from a SISO processing unit is assumed to be as follows:

y=[1 −½ ½−1 1 1]

Additionally, in the description of the soft decoding methods with reference to FIGS. 9A through 12, for example, Y=LLR_{LDPC}^{int}(vi)=[2 −1 1 −2 2 2].

In FIGS. 9A through 9C, by way of example, error correction is performed without changing a defective section corresponding to a defect signal. In FIGS. 10 through 12, by way of example, error correction is performed by changing a soft value corresponding to a generated defect signal into a predetermined value. In the following description, by way of example, it is assumed that a defect signal generating unit generates a defect signal indicating that second and third bits of Y are defective.

FIG. 9A shows, by way of example, a first correction when error correction is performed without changing a defective section corresponding to a defect signal. FIG. 9B shows, by way of example, a second correction, and FIG. 9C shows, by way of example, a third correction, when error correction is performed without changing a defective section corresponding to a defect signal.

Referring to FIG. 9A, H and Y are multiplied to generate LLR₍₁₎(qⱼᵢ) in operation 910. Multiplication is performed such that each “1” of each row of H is multiplied by an element of Y arranged corresponding to the position of each “1” and the multiplication result is arranged in each corresponding row of LLR₍₁₎(qⱼᵢ). For example, in the first row of LLR₍₁₎(qⱼᵢ), q₁₁ is 2*1=“2” by p₁*h₁₁, q₁₂ is −1*1=“−1” by p₂*h₁₂, and q₁₄ is −2*1=“−2” by p₄*h₁₄. In this way, for example, LLR₍₁₎(qⱼᵢ) is generated.

Next, LLR₍₁₎(qⱼᵢ) is converted into LLR₍₁₎(rⱼᵢ) in operation 920. The conversion is performed as follows. The sign and value of r₁₁ in the first row and first column of LLR₍₁₎(rⱼᵢ) are determined by the remaining elements in the first row and first column of LLR₍₁₎(qⱼᵢ) except for q₁₁. For example, the sign and value of r₁₁ are determined by q₁₂ and q₁₄. In other words, the sign of r₁₁ is determined by whether q₁₂ and q₁₄ are negative or positive to satisfy a condition that the number of positive elements is even. Since both q₁₂ and q₁₄ are negative, the number of positive elements is “0”. Since the number of positive elements is already even, r₁₁ should be negative. The value of r₁₁ is determined by the values of q₁₂ and q₁₄. The absolute value of q₁₂ is “1” and the absolute value of q₁₄ is “2”, and the minimum value of the two absolute values is determined to be the value of r₁₁. Thus, in this case, the value of r₁₁ is “1”. Since the value of r₁₁ is “1” and r₁₁ is negative, r₁₁ is “−1”. In this way, the other elements of LLR₍₁₎(rⱼᵢ) are obtained in operation 920.

Next, LLR₍₁₎(rⱼᵢ) and Y are added to generate LLR₍₁₎(qᵢ) in operation 930. The addition is performed such that all elements in each column of LLR₍₁₎(rⱼᵢ) and an element of Y in each corresponding column to a column of LLR₍₁₎(rⱼᵢ) are added. For example, the first element of LLR₍₁₎(qᵢ) is calculated, or determined, by adding “−1” and “−1” in the first column of LLR₍₁₎(rⱼᵢ) and “2” in the first column of Y. Thus, the first element of LLR₍₁₎(qᵢ) is “0”. In this way, for example, the other elements of LLR₍₁₎(qᵢ) are obtained in operation 930.

Next, in operation 930, LLR₍₁₎(qᵢ) is converted into v(1). The conversion is performed such that if an element of LLR₍₁₎(qᵢ) is “0”, a corresponding element of v(1) is an unknown value, if an element of LLR₍₁₎(qᵢ) is negative, a corresponding element of v(1) is “0”, and if element of LLR₍₁₎(qᵢ) is positive, a corresponding element of v(1) is “1”. Thus, v(1)=[? ? ? 0 1 1]. Since the obtained v(1) is not the same as the original v [1 1 0 0 1 1], the second correction starts.

Referring to FIG. 9B, the second correction is similar to first correction except for operation 940. When LLR₍₂₎(qⱼᵢ) is obtained in operation 940, LLR₍₁₎(rⱼᵢ) is used instead of H. In other words, LLR₍₂₎(qⱼᵢ) is obtained using Y and LLR₍₁₎(rⱼᵢ) as follows.

In the second correction illustrated in FIG. 9B, an element in each column of LLR₍₂₎(qⱼᵢ) is obtained using the remaining element in a corresponding column of LLR₍₁₎(rⱼᵢ) except for an element arranged in a corresponding row and the corresponding column of LLR₍₁₎(rⱼᵢ) and using an element in a corresponding column of Y. For example, when q₁₁ in the first row and first column of LLR₍₂₎(qⱼᵢ) is obtained, p₁ in the first column of Y and r₃₁ in the first column of LLR₍₁₎(rⱼᵢ) remaining except for r₁₁ in the first row and first column of LLR₍₁₎(rⱼᵢ) are added. Since p₁ is “2” and r₃₁ is “−1”, q₁₁ is “1”. In this way, the other elements of LLR₍₂₎(qⱼᵢ) are obtained. The other operations 950 and 960 are similar to operations 920 and 930, as previously described in connection with FIG. 9A.

In operation 960, since v(2) obtained through second correction is [0 1 0 0 1 1] and is not the same as the original v, the third correction starts. Referring to FIG. 9C, operations 970, 980 and 990 of the third correction are similar to operations 940, 950 and 960 of the second correction, as previously described in connection with FIG. 9B. Since v(3) obtained through third correction in operation 990 is [1 0 1 0 1 1] and is not the same as original v, the third correction also fails.

As such, when error correction is performed without changing a defective section corresponding to a defect signal, the third correction also fails. If LLR₍₄₎(qⱼᵢ) is obtained, LLR₍₄₎(qⱼᵢ) is the same as LLR₍₁₎(qⱼᵢ). Thus, in operations of FIGS. 9A through 9C, an error typically cannot be corrected by decoding using “MIN Approximation”.

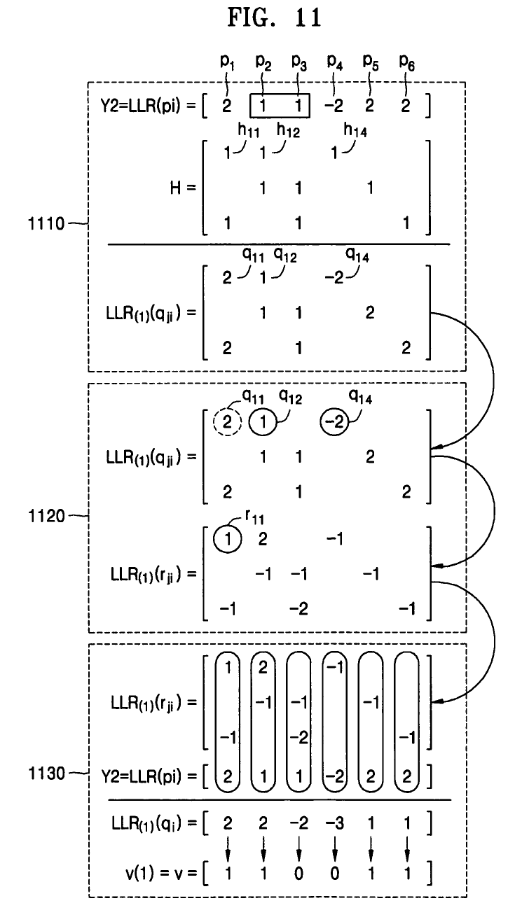

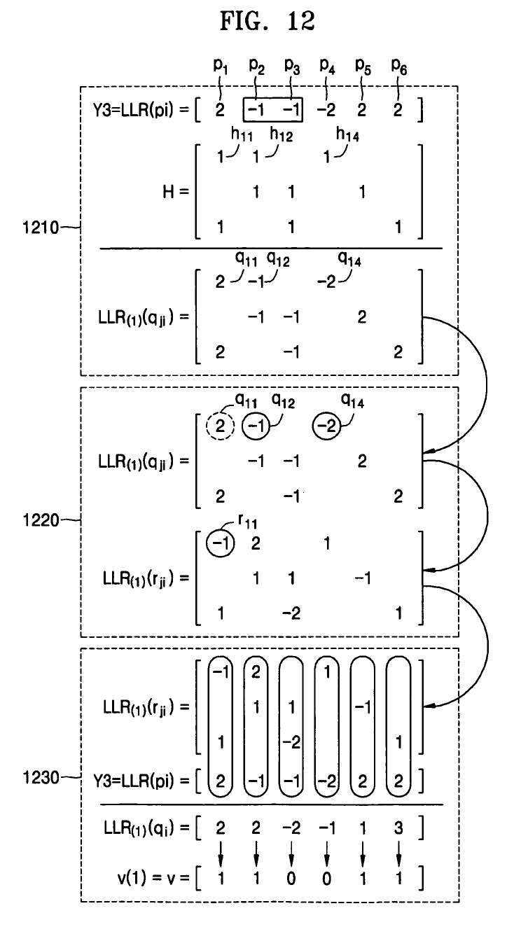

Error correction performed after detecting a defect signal and changing a defective section corresponding to the defect signal into a predetermined value, according to aspects of the present invention, is described with reference to FIGS. 10 through 12. The predetermined value is “0” in FIG. 10, “1” in FIG. 11, and “−1” in FIG. 12, by way of example.

Referring to FIG. 10, in Y1, second and third defective signals P₂ and P₃ of the original signal Y are each substituted by 0, by way of example. Further, operations 1010, 1020, and 1030 of FIG. 10 are similar to the operations 910, 920, and 930, as described in the error correction of FIG. 9A. H and Y1 are multiplied to generate LLR₍₁₎(qⱼᵢ) in operation 1010. Further, q₁₁, q₁₂, and q₁₄ in the first row of LLR₍₁₎(qⱼᵢ) are p₁*h₁₁=2*1=“2”, p₂*h₁₂=0*1=“0”, and p₄*h₁₄=−2*1=“−2”, respectively.

LLR₍₁₎(qⱼᵢ) is converted into LLR₍₁₎(rⱼᵢ) in operation 1020. In operation 1020, r₁₁ in the first row and first column of LLR₍₁₎(rⱼᵢ) is obtained using q₁₂ and q₁₄. In LLR₍₁₎(qⱼᵢ), q₁₂ is neither positive nor negative and q₁₄ is negative. Since the number of positive elements should be even, r₁₁ should be negative. Since the minimum value of the absolute values of q₁₂ and q₁₄ is “0”, r₁₁ has a value of “0” and a negative sign. Thus, r₁₁ is “0”. In this way, the other elements of LLR₍₁₎(rⱼᵢ) are obtained. Further, LLR₍₁₎(qᵢ) is obtained by adding LLR₍₁₎(rⱼᵢ) and Y1 in operation 1030.

Thus, in operation 1030, LLR₍₁₎(qᵢ) is [2 2 −2 −2 2 2]. The conversion in operation 1030 is performed such that if an element of LLR₍₁₎(qᵢ) is “0”, a corresponding element of v(1) is an unknown value, if an element of LLR₍₁₎(qᵢ) is negative, a corresponding element of v(1) is “0”, and if an element of LLR₍₁₎(qᵢ) is positive, a corresponding element of v(1) is “1”; and v(1) in operation 1030 is [1 1 0 0 1 1]. Thus, the obtained v(1) in operation 1030 is the same as the original v. As such, when error correction is performed after changing a defective section corresponding to a defect signal into a predetermined value of “0”, according to aspects of the invention, error correction can be successful in a first attempt.

Referring to FIG. 11, in Y2, second and third defective signals P₂ and P₃ of the original signal Y are each substituted by “1”, by way of example. Operations 1110, 1120, and 1130 of FIG. 11 are similar to the operations 910, 920, and 930, as described in the error correction of FIG. 9A. H and Y2 are multiplied to generate LLR₍₁₎(qⱼᵢ) in operation 1110. Further, q₁₁, q₁₂, and q₁₄ in the first row of LLR₍₁₎(qⱼᵢ) are p₁*h₁₁=2*1=“2”, p₂*h₁₂=1*1=“1”, and p₄*h₁₄=−2*1=“−2”, respectively.

LLR₍₁₎(qⱼᵢ) is converted into LLR₍₁₎(rⱼᵢ) in operation 1120. In operation 1120, r₁₁ in the first row and first column of LLR₍₁₎(rⱼᵢ) is obtained using q₁₂ and q₁₄. In LLR₍₁₎(qⱼᵢ), q₁₂ is positive and q₁₄ is negative. Since the number of positive elements should be even, r₁₁ should be positive. Since the minimum value of the absolute values of q₁₂ and q₁₄ is “1”, r₁₁ has a value of “1” and a positive sign. Thus, r₁₁ is “1”. In this way, the other elements of LLR₍₁₎(rⱼᵢ) are obtained. Further, LLR₍₁₎(qᵢ) is obtained by adding LLR₍₁₎(rⱼᵢ) and Y2 in operation 1130.

Thus, in operation 1130, LLR₍₁₎(qᵢ) is obtained as [2 2 −2 −3 1 1]. The conversion in operation 1130 is performed such that if an element of LLR₍₁₎(qᵢ) is “0”, a corresponding element of v(1) is an unknown value, if an element of LLR₍₁₎(qᵢ) is negative, a corresponding element of v(1) is “0”, and if an element of LLR₍₁₎(qᵢ) is positive, a corresponding element of v(1) is “1”; and v(1) in operation 1130 is [1 1 0 0 1 1]. Thus, the obtained v(1) in operation 1130 is the same as the original v. As such, when error correction is performed after changing a defective section corresponding to a defect signal into a predetermined value of “1”, according to aspects of the invention, error correction can be successful in a first attempt.

Referring to FIG. 12, in Y3, second and third defective signals P₂ and P₃ of the original signal Y are each substituted by “−1”, by way of example. Operations 1210, 1220, and 1230 of FIG. 12 are similar to the operations 910, 920, and 930, as described in the error correction of FIG. 9A. H and Y3 are multiplied to generate LLR₍₁₎(qⱼᵢ) in operation 1210. Further, q₁₁, q₁₂, and q₁₄ in the first row of LLR₍₁₎(qⱼᵢ) are p₁*h₁₁=2*1=“2”, p₂*h₁₂=−1*1=“−1”, and p₄*h₁₄=−2*1=“−2”, respectively.

LLR₍₁₎(qⱼᵢ) is converted into LLR₍₁₎(rⱼᵢ) in operation 1220. In operation 1220, r₁₁ in the first row and first column of LLR₍₁₎(rⱼᵢ) is obtained using q₁₂ and q₁₄. Both q₁₂ and the sign of q₁₄ are negative. Since the number of positive elements should be even, r₁₁ should be negative. Since the minimum value of the absolute values of q₁₂ and q₁₄ is “1”, r₁₁ has a value of “1” and a negative sign. Thus, r₁₁ is “−1”. In this way, the other elements of LLR₍₁₎(rⱼᵢ) are obtained. Further, LLR₍₁₎(qᵢ) is obtained by adding LLR₍₁₎(rⱼᵢ) and Y3 in operation 1230.

Thus, in operation 1230, LLR₍₁₎(qᵢ) is obtained as [2 2 −2 −1 1 3]. The conversion in operation 1230 is performed such that if an element of LLR₍₁₎(qᵢ) is “0”, a corresponding element of v(1) is an unknown value, if an element of LLR₍₁₎(qᵢ) is negative, a corresponding element of v(1) is “0”, and if an element of LLR₍₁₎(qᵢ) is positive, a corresponding element of v(1) is “1”; and

v(1) in operation 1230 is [1 1 0 0 1 1]. Thus, the obtained v(1) in operation 1230 is the same as the original v. As such, when error correction is performed after changing a defective section corresponding to a defect signal into a predetermined value of “−1”, according to aspects of the invention, error correction can be successful in a first attempt.

In the example embodiments described above, with reference to FIGS. 11 and 12, in Y2 and Y3, even when a defective section corresponding to a defect signal is changed into a specific value, an error occurs in only a portion of the original signal. This means error correction may not be performed when the specific value is set to “1” or “−1” as in Y2 and Y3. However, when the soft value of a bit corresponding to a defective section where a defect occurs is set to “0” as in Y1, with reference to FIG. 10, error correction can typically be performed at all times.

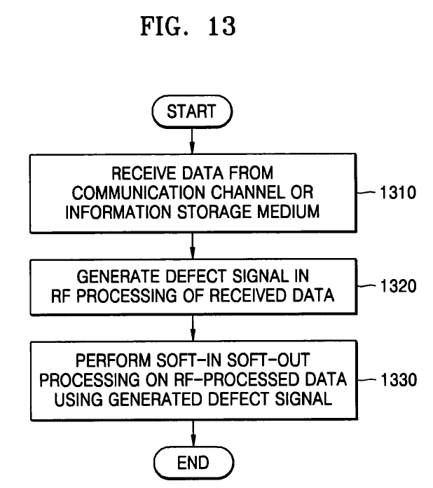

FIG. 13 is a flowchart illustrating a soft output method according to an embodiment and aspects of the present invention. A soft output apparatus, as described, for example, in FIG. 2 and/or FIG. 6, receives data from a communication channel or an information storage medium in operation 1310. The soft output apparatus performs RF processing on the received data and generates a defect signal for the RF-processed data in operation 1320. In this regard and by way of example, the soft output apparatus detects a defective section having a high possibility of a defect occurring from the RF-processed data and generates a defect signal for the detected defective section.

The soft output apparatus performs SISO processing on the RF-processed data using the generated defect signal in operation 1330. In this regard and by way of example, the soft output apparatus changes the soft values of all or some bits corresponding to the defective section for which the defect signal is generated into a predetermined soft value, performs SISO processing on the soft values, and outputs the SISO-processed soft values.

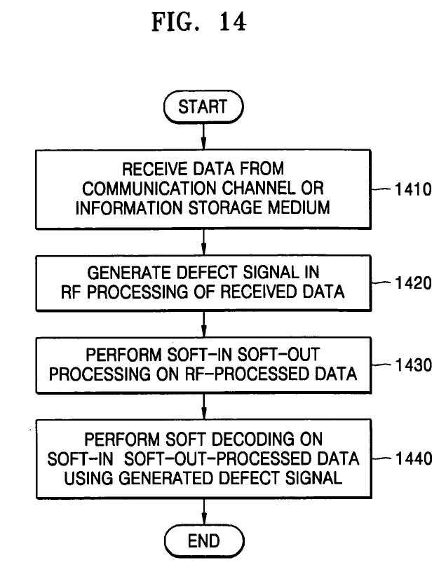

FIG. 14 is a flowchart illustrating a soft decoding method according to an embodiment and aspects of the present invention. A soft decoding apparatus, as described, for example, in FIG. 3, FIG. 4, FIG. 7 and/or FIG. 8, receives data from a communication channel or an information storage medium in operation 1410. The soft decoding apparatus generates a defect signal when RF processing is performed on the received data in operation 1420. In this regard and by way of example, the soft decoding apparatus detects a defective section having a high possibility of a defect occurring from the received data and generates a defect signal for the detected defective section.

The soft decoding apparatus performs SISO processing on the RF-processed data in operation 1430. In operation 1440, the soft decoding apparatus performs soft decoding on the SISO-processed data using the defect signal generated in operation 1420. In this regard and by way of example, the soft decoding apparatus performs soft decoding after changing the soft values of all or some bits corresponding to the defective section for which the defect signal is generated into a predetermined value.

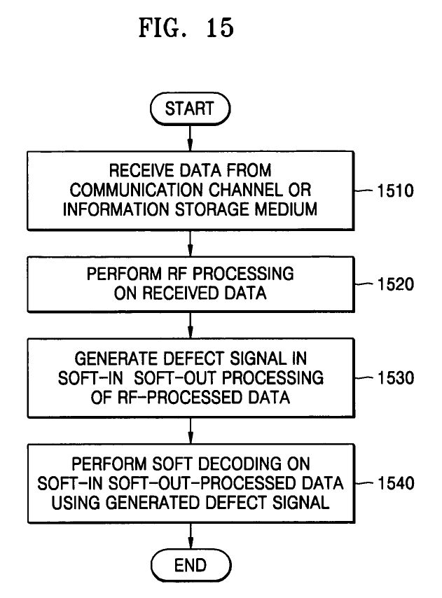

FIG. 15 is a flowchart illustrating a soft decoding method according to another embodiment and aspects of the present invention. A soft decoding apparatus, as described, for example, in FIG. 3, FIG. 4, FIG. 7 and/or FIG. 8, receives data from a communication channel or an information storage medium in operation 1510. In operation 1520, the soft decoding apparatus performs RF processing on the received data.

The soft decoding apparatus generates a defect signal when SISO processing is performed on the RF-processed data in operation 1530. In this regard and by way of example, the soft decoding apparatus detects a defective section having a high possibility of a defect occurring from the received data and generates a defect signal for the detected defective section. In operation 1540, the soft decoding apparatus performs soft decoding on the SISO-processed data using the defect signal generated in operation 1530 after changing the soft values of all or some bits corresponding to the defective section for which the defect signal is generated into a predetermined value.

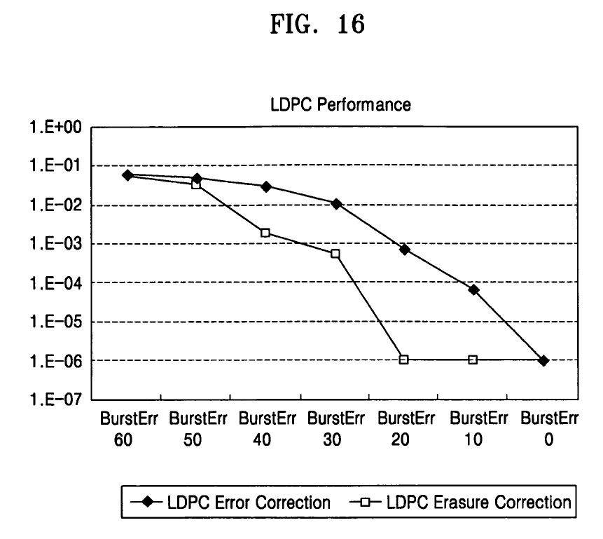

FIG. 16 is a graph to compare the performance of known LDPC error correction and the performance of LDPC erasure correction according to example embodiments and aspects of the present invention. Referring to FIG. 16, by way of example, the simulation result of a burst error of LDPC (N, K)=(9216, 8192) having a codeword length of 9216 and a code rate of 8/9 undergoes erasure correction where a soft value for a defective section is set to a mean value between “0” and “1” according to embodiments and aspects of the present invention. Error correction is directly performed on an input signal, and the simulation results by software can be expressed as a graph, such as illustrated in FIG. 16.

The graph, an example of which is illustrated in FIG. 16, is further described as follows.

Simulation size: 64 (N, K)=(9216, 8192) LDPC codewords are interleaved to construct one ECC block, and a total of 4 ECC blocks are constructed; and

ECC block: One ECC block having a data bit size of 64*9216 is modulated with RLL (1, 7) code, where, after modulation, the ECC block has a channel bit size of 64*9216*3/2.

An RF signal that passes through an analog-to-digital converter (ADC) reflecting an inter symbol interface (ISI) and additive white gaussian noise (AWGN) is obtained through software simulation. A defective section BurstErrN (N=0, 10, 20, 30, 40, 50, and 60) is artificially added to the same position in ECC blocks of the RF signal obtained through software (S/W) simulation. The RF signal undergoes SISO processing including soft output viterbi decoding (SOVD) and soft demodulation and is input to an LDPC decoder. Thus, the results of LDPC error correction directly performed on the input RF signal and LDPC erasure correction, where a soft value for the defective section BurstErrN is substituted by the mean value between “0” and “1”, are compared, such as illustrated in FIG. 16.

When the RF signal passing through the ADC to which a defect is not added is compared with original data after undergoing SISO processing, its bit error rate is “0”. BurstErr0 is the RF signal that undergoes the ADC conversion, i.e., to which a defect is not added. BurstErrN (N=10, 20, 30, 40, 50, 60) is input to a SISO processing unit with a level of “0” of the RF signal passing through the ADC for a length corresponding to Nx1860 channel bits in one ECC block. The level of the RF signal passing through the ADC is typically “0”. In this regard and by way of example, a general RF signal passing through the ADC read from a disc typically has a value between the maximum value and the minimum value in relation to the amount of reflection of a signal from the disc in a non-defective section to which data is recorded.

For example, when the ADC is configured with 8 bits, its signal level is between “128” and “−128”. However, in a defective section of the disc where a defect occurs, due to a difference in the amount of reflection, the level of the RF signal passing through the ADC approaches “0” as the defect is typically considered to be serious. In this regard and by way of example, according to aspects of the present invention, the level of the RF signal passing through the ADC is typically set to “0” and is input to the SISO processing unit. After the level of the RF signal passing through the ADC is substituted by “0” in a defective section, and the RF signal is input to the SISO processing unit, the SISO-processed data has an error of about 40% to about 60% of bits included in the defective section when compared to the original data.

As described, according to aspects of the present invention, by changing a soft value for a defective section having low data reliability due to a defect into a predetermined value, the reliability of data degraded due to the defect can be improved, thereby improving the performance of decoding.

Further, the error correction method according to an embodiment and aspects of the present invention can also be embodied as a computer-readable code on a computer-readable recording medium. The computer-readable recording medium can be a suitable data storage device that can store data which thereafter can be read by a computer system. Examples of the computer-readable recording medium include read-only memory (ROM), random-access memory (RAM), compact disc read only memories (CD-ROMs), magnetic tapes, floppy disks, optical data storage devices, and carrier waves. The computer-readable recording medium, according to aspects of the invention, can also be distributed over network coupled computer systems so that the computer-readable code can be stored and executed in a distributed fashion, such as the function program, code and code segments, to implement error correction.

While there have been illustrated and described what are considered to be example embodiments of the present invention, it will be understood by those skilled in the art that various changes in form and modification may be made therein, and equivalents may be substituted for elements thereof without departing from the spirit and scope of the present invention. For example, as described, an error correction method, according to an embodiment and aspects of the invention, can also be embodied as a computer-readable code on a computer-readable recording medium, or distributed over network coupled computer systems or transmission systems so that the computer-readable code can be stored and executed in a distributed fashion, such as over a wired or wireless network. Accordingly, it is intended, therefore, that that present invention not be limited to the various example embodiments disclosed, but that the present invention includes all embodiments falling within the scope of the appended claims.

What is claimed is:

1. A method of decoding a codeword encoded into a code that can be soft iterative decoded, the method comprising:
receiving soft values, each soft value corresponding to a bit of a received codeword;
generating a defect signal corresponding to the received codeword; and
changing soft values of one or more bits corresponding to the generated defect signal into a predetermined value to perform error correction.

2. The method of claim 1, wherein the predetermined value indicates that the probability of a bit being “0” and the probability of the bit being “1” are the same.

3. The method of claim 1, wherein the predetermined value is determined by an error correction characteristic of a low density parity check.

4. The method of claim 1, wherein the receiving of the soft values comprises receiving the soft values from a communication channel.

5. The method of claim 1, wherein the generation of the defect signal comprises:
detecting at least one or more sections, including a section where data is not synchronous in data reception, a section where a phase-locked loop (PLL) error occurs, a section where a synchronization error is generated during soft demodulation, or a section comprising a pattern that does not exist among modulated patterns; and
generating the defect signal corresponding to the entire detected section or a part of the detected section.

6. The method of claim 1, wherein the receiving of the soft values comprises receiving the soft values from an information storage medium.

7. The method of claim 1, wherein the generation of the defect signal comprises:
detecting at least one or more sections, including a section where a servo error occurs, a section where the reliability of data is determined to be low corresponding to the amount of reflection from a pickup, a section where a phase-locked loop (PLL) or a synchronization error is detected, or a section comprising a pattern that does not exist among modulated patterns, and
generating the defect signal corresponding to the entire detected section or a part of the entire detected section.

8. A method of performing error correction on a codeword encoded into a code that can be soft iterative decoded, the method comprising:
changing soft values of one or more bits corresponding to a defect signal of the encoded codeword into a predetermined value; and
performing iterative correction based on each changed soft value.

9. An apparatus to decode a codeword encoded into a code that can be soft iterative decoded, the apparatus comprising:
a receiving unit to receive soft values, with each soft value corresponding to a bit of a received codeword;
a defect signal generating unit to generate a defect signal corresponding to the received codeword; and
a soft decoder to change soft values of one or more bits corresponding to the generated defect signal into a predetermined value to perform error correction.

10. The apparatus of claim 9, wherein the soft decoder determines a value indicating that the probability of a bit being “0” and the probability of the bit being “1” are the same as the predetermined value.

11. The apparatus of claim 9, wherein the soft decoder determines the predetermined value according to an error correction characteristic of a low density parity check.

12. The apparatus of claim 9, wherein the receiving unit receives the soft values from a communication channel.

13. The apparatus of claim 12, wherein the defect signal generating unit detects at least one or more sections, including a section where data is not synchronous in data reception, a section where a phase-locked loop (PLL) error occurs, a section where a synchronization error is generated during soft demodulation, or a section comprising a pattern that does not exist among modulated patterns, and generates the defect signal for the entire detected section or a part of the entire detected section.

14. The apparatus of claim 9, wherein the receiving unit receives the soft values from an information data storage medium.

15. The apparatus of claim 14, wherein the defect signal generating unit detects at least one or more sections, including a section where a servo error occurs, a section where the reliability of data is determined to be low corresponding to the amount of reflection from a pickup, a section where a phase-locked loop (PLL) or a synchronization error is detected, or a section comprising a pattern that does not exist among modulated patterns, and generates the defect signal for the entire detected section or a part of the entire detected section.

16. An apparatus to perform error correction on a codeword encoded into a code that can be soft iterative decoded, the apparatus comprising:
a soft decoder to change soft values of one or more bits corresponding to a defect signal of the encoded codeword into a predetermined value and to perform iterative correction based on each changed soft value.

17. A method of outputting a soft value from a codeword encoded into a code that can be soft iterative decoded, the method comprising:
receiving soft values, each soft value corresponding to a bit of a received codeword;
generating a defect signal corresponding to the received codeword; and
changing soft values of one or more bits corresponding to the generated defect signal into a predetermined value and outputting each changed soft value.

18. The method of claim 17, wherein the predetermined value indicates that the probability of a bit being “0” and the probability of the bit being “1” are the same.

19. The method of claim 17, wherein the predetermined value is determined by an error correction characteristic of a low density parity check.

20. An apparatus to output a soft value from a codeword encoded into a code that can be soft iterative decoded, the apparatus comprising:
a receiving unit to receive soft values, each soft value corresponding to a bit of a received codeword;
a defect signal generating unit to generate a defect signal corresponding to the received codeword; and
a soft-in soft-out (SISO) processing unit to change soft values of one or more bits corresponding to the generated defect signal into a predetermined value and outputting each changed soft value.

21. The apparatus of claim 20, wherein the SISO processing unit determines a value indicating that the probability of a bit being “0” and the probability of the bit being “1” are the same as the predetermined value.

22. The apparatus of claim 21, wherein the SISO processing unit determines the predetermined value according to an error correction characteristic of a low density parity check.

23. The apparatus of claim 20, wherein the SISO processing unit determines the predetermined value according to an error correction characteristic of a low density parity check.

24. The method of claim 18, wherein the predetermined value is determined by an error correction characteristic of a low density parity check.

25. The apparatus of claim 10, wherein the soft decoder determines the predetermined value according to an error correction characteristic of a low density parity check.

26. The method of claim 2, wherein the predetermined value is determined by an error correction characteristic of a low density parity check.

27. A computer readable medium having computer-executable instructions for performing a method of decoding a codeword encoded into a code that can be soft iterative decoded comprising:
receiving soft values, each soft value corresponding to a bit of a received codeword;
generating a defect signal corresponding to the received codeword; and
changing soft values of one or more bits corresponding to the generated defect signal into a predetermined value to perform error correction.

28. The computer readable medium of claim 27, wherein the method further comprises:
determining the predetermined value by an error correction characteristic of a low density parity check.

29. A computer readable medium having computer-executable instructions for performing a method of error correction on a codeword encoded into a code that can be soft iterative decoded comprising:
changing soft values of one or more bits corresponding to a defect signal of the encoded codeword into a predetermined value; and
performing iterative correction based on each changed soft value.

30. A computer readable medium having computer-executable instructions for performing a method of outputting a soft value from a codeword encoded into a code that can be soft iterative decoded comprising:
receiving soft values, each soft value corresponding to a bit of a received codeword;
generating a defect signal corresponding to the received codeword; and
changing soft values of one or more bits corresponding to the generated defect signal into a predetermined value and outputting each changed soft value.

31. The computer readable medium of claim 30, wherein the method further comprises:
determining the predetermined value by an error correction characteristic of a low density parity check.
